(19) United States
(12) Patent Application Publication
(10) Pub. No.: US 2026/0268058 A1
(43) Pub. Date: Sep. 10, 2026

(54) METHOD AND COMPUTING SYSTEM FOR DESIGNING INTEGRATED CIRCUIT

(71) Applicant: SAMSUNG ELECTRONICS CO., LTD., Suwon-si (KR)

(72) Inventor: Kiwon YOON, Suwon-si (KR)

(73) Assignee: SAMSUNG ELECTRONICS CO., LTD., Suwon-si (KR)

(21) Appl. No.: 19/553,978

(22) Filed: Mar. 2, 2026

(30) Foreign Application Priority Data
Mar. 7, 2025 (KR) 10-2025-0030065
Sep. 1, 2025 (KR) 10-2025-0123520

(51) Int. Cl. G06F 30/392

(52) U.S. Cl. CPC G06F 30/392

(57) ABSTRACT

The method is performed by the computing system and includes extracting first process information and first floorplan information from a first floorplan of a first process, receiving second process information of a second process, determining a shape and a size of a second floorplan based on the first process information, the first floorplan information and the second process information, determining locations of ports and a location of a blockage area in the second floorplan, and generating second floorplan information of the second floorplan based on the shape and the size of the second floorplan, and the locations of the ports and the location of the blockage area in the second floorplan.

### CROSS-REFERENCE TO RELATED APPLICATIONS

This application is based on and claims priority under 35 U.S.C. §119 to Korean Patent Application Nos. 10-2025-0030065, filed on Mar. 7, 2025 and 10-2025-0123520, filed on Sep. 1, 2025 in the Korean Intellectual Property Office, the disclosures of which are incorporated by reference herein in their entireties.

### BACKGROUND

The present disclosure relates to a method and computing system for designing an integrated circuit, and more particularly, to a method and computing system for designing an integrated circuit, whereby a floorplan of a new process may be generated using a floorplan of initial process.

When designing integrated circuits, some digital circuits within an integrated circuit are redesigned by changing only a process while maintaining their function. In order to redesign a digital circuit of which the design has been completed in an initial process in a new process, the design process has to be repeated from the beginning, and design rules appropriate for the new process have to be applied to each design process.

### SUMMARY

One or more embodiments provide a method and computing system for designing an integrated circuit, whereby a floorplan of a new process may be generated using a floorplan of an initial process.

According to an aspect of an embodiment, a method of designing an integrated circuit performed by a computing system, includes: extracting first process information and first floorplan information from a first floorplan of a first process; receiving second process information of a second process; determining a shape and a size of a second floorplan based on the first process information, the first floorplan information and the second process information; determining locations of ports and a location of a blockage area in the second floorplan; and generating second floorplan information of the second floorplan based on the shape and the size of the second floorplan, and the locations of the ports and the location of the blockage area in the second floorplan.

According to another aspect of an embodiment, a method of designing an integrated circuit performed by a computing system, includes: based on first process information of a first process, first floorplan information of the first process, and second process information of a second process, determining a shape and a size of a second floorplan of the second process; based on the first floorplan information, determining locations of ports and a location of a blockage area to be arranged in the second floorplan; and generating second floorplan information of the second floorplan based on the shape and the size of the second floorplan, the locations of the ports and the location of the blockage area.

According to another aspect of an embodiment, a computing system includes: one or more memories storing instructions; and one or more processors configured to execute the instructions to: extract first process information and first floorplan information from a floorplan of a first process; determine a shape and a size of a second floorplan of a second process based on the first process information, the first floorplan information and second process information of the second process; determine locations of ports and a location of a blockage area arranged in the second floorplan; and generate second floorplan information of the second floorplan based on the shape and the size of the second floorplan, and the locations of the ports and the location of the blockage area in the second floorplan.

### BRIEF DESCRIPTION OF DRAWINGS

The above and other objects and features will be more clearly understood from the following description of embodiments, taken in conjunction with the accompanying drawings, in which:

FIG. 1 is a flowchart illustrating a method of designing an integrated circuit according to an embodiment;

FIG. 2 illustrates a floorplan operation in a method of designing an integrated circuit according to an embodiment;

FIG. 3 is a flowchart illustrating a method of designing an integrated circuit according to an embodiment;

FIGS. 4 through 6 are views for explaining a method of designing an integrated circuit according to an embodiment;

FIG. 7 is a flowchart illustrating a method of designing an integrated circuit according to an embodiment;

FIGS. 8 and 9 are views for explaining a method of designing an integrated circuit according to an embodiment;

FIG. 10 is a flowchart illustrating a method of designing an integrated circuit according to an embodiment;

FIG. 11 is a view for explaining a method of designing an integrated circuit according to an embodiment;

FIG. 12 is a block diagram illustrating a computing system including memory in which a program for designing an integrated circuit is stored, according to an embodiment; and

FIG. 13 is a block diagram for explaining an example of a program stored in a memory according to an embodiment.

### DETAILED DESCRIPTION

Hereinafter, embodiments of the disclosure will be described in detail with reference to the accompanying drawings. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

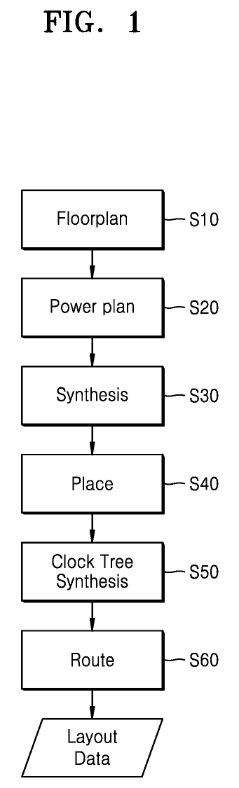

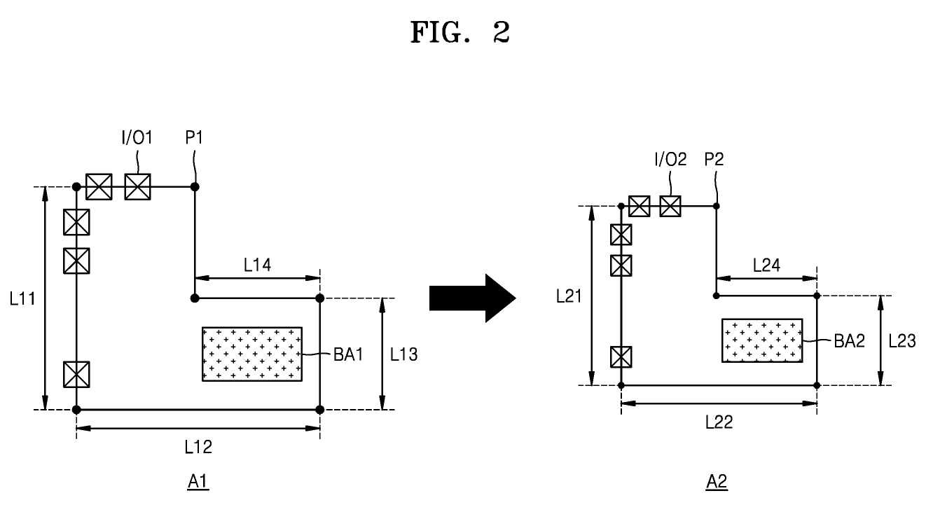

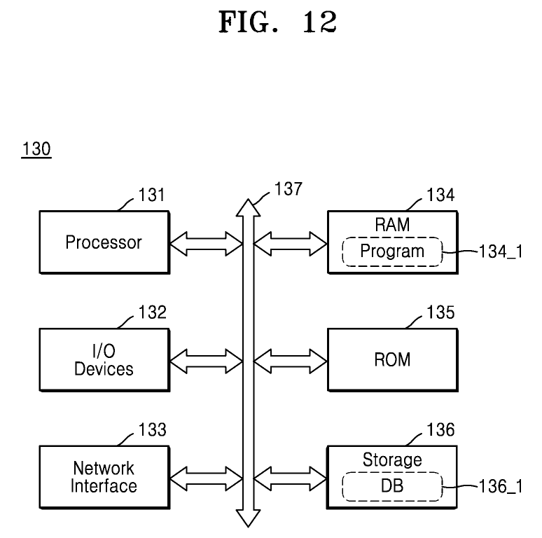

FIG. 1 is a flowchart illustrating a method of designing an integrated circuit according to an embodiment. FIG. 2 illustrates a floorplan operation in a method of designing an integrated circuit according to an embodiment. The method of designing the integrated circuit to be described with reference to FIG. 1 and the like may be an operation of designing a layout of the integrated circuit and may be performed by a computing system (e.g., computing system 130 of FIG. 12). A computing system 130 may include a storage device storing a plurality of commands to be executed by a processor. Thus, the present designing procedure may be a computer-implemented operation for designing the integrated circuit. A process for manufacturing a semiconductor device based on the designed layout may be performed in a semiconductor process module.

Referring to FIG. 1, a method of designing an integrated circuit may be performed by receiving information for designing the integrated circuit (e.g., integrated circuit production facility information, node information of a block, tool information for design, etc.), and may include a floorplan operation S10, a power plan operation S20, a logic synthesis operation S30, a place operation S40, a clock tree synthesis (CTS) operation S50, and a route operation S60.

The floorplan operation S10 may be an operation in which a logically designed schematic circuit is cut and moved to be physically designed. For example, floorplan may indicate information about a space in which blocks included in the integrated circuit are arranged, and may indicate schematic arrangement information of gates in each of the blocks. Memory or circuit function blocks may be arranged in the floorplan operation S10. For example, circuit function blocks that have to be arranged adjacently may be identified, and space for the circuit function blocks may be allocated in consideration of available space and required performance. In addition, in the floorplan operation S10, for example, information about the size of space for a circuit function block (e.g., width and height size) may be determined, and the locations of input/output ports arranged in the circuit function block, the size and locations of macro cells arranged within the circuit function block, the size and location of a blockage area within the circuit function block, etc., may be determined. The blockage area may indicate an area in which arrangement of power lines (or power vias) is not allowed in the power plan operation S20. Floorplan information may be generated in the floorplan operation S10.

The power plan operation S20 may be an operation in which patterns of wires for connecting local power, for example, a driving power supply voltage (e.g., VDD) or a ground voltage (e.g., VSS), to the arranged circuit function blocks. The power plan operation S20 may be performed based on the floorplan information. For example, wiring patterns of power lines connecting the power supply voltage or the ground voltage may be generated within a circuit function block in the form of a net so that power may be supplied evenly throughout the integrated circuit (or chip). In the present operation, the wiring patterns may be generated in a net form through various rules.

In the logic synthesis operation S30, a logic synthesis operation of generating netlist data from register-transfer level (RTL) data may be performed. For example, a semiconductor design tool (e.g., a logic synthesis module) may generate netlist data including a bitstream or netlist by performing logic synthesis from RTL data written in a hardware description language (HDL) such as very-high speed integrated circuits (VHSIC) hardware description language (VHDL) and Verilog by referencing a standard cell library. The standard cell library may include data for defining the structure of standard cells having different layouts and performing the same function, and standard cells may be included in the integrated circuit by referring to the standard cell library in the logic synthesis operation.

The place operation S40 is an operation in which patterns of elements constituting the circuit function block are arranged, and may include an operation in which standard cells from the standard cell library are arranged. There may be blank areas between the standard cells, and these blank areas may be filled by filler cells. Unlike the standard cells, the filler cells may include dummy areas.

By the present operation, the shape and size of patterns for configuring transistors and wires to be actually formed on a silicon substrate may be defined. For example, in order to form an inverter circuit on an actual silicon substrate, layout patterns such as p-type metal oxide semiconductor (PMOS) transistors, n-type metal oxide semiconductor (NMOS) transistors, n-type well, gate electrodes, and wires to be arranged thereon may be appropriately arranged. In an embodiment, even after the place operation S40, the CTS operation S50, or the route operation S60 described below have been performed, the place operation S40 may be re-performed depending on the verification result.

The CTS operation S50 may be an operation in which patterns for signal lines of a center clock relating to the operating speed for determining the performance of the semiconductor device are generated.

The route operation S60 may be an operation in which a wiring structure for connecting the standard cells arranged as defined are generated. The wiring structure may be electrically connected to wires within the standard cells, the standard cells may be electrically connected to each other, and input pins or output pins of the standard cells may be connected to each other.

Subsequently, the results of the place operation S40, the CTS operation S50, and the route operation S60 may be verified. For example, a timing engineering change order (ECO) operation may be further performed, and a predetermined physical design rule check (DRC) and correction may be performed.

In an embodiment, the timing ECO operation may include a static timing analysis (STA) operation and a timing update operation. For example, the timing ECO operation may include a timing optimization operation, and for verification, the timing ECO operation may include an operation for determining whether there is a timing violation or not. For example, it may be determined whether there is a setup timing violation or hold timing violation of a flip-flop.

When operations S10 to S60 of designing the integrated circuit described above are completed, layout data may be generated, and thereafter, based on the layout data, an optical proximity correction (OPC) operation, an operation of manufacturing a mask, and an operation of fabricating an integrated circuit may be performed. OPC may refer to a work of forming patterns of a desired shape by correcting distortion phenomena such as refraction caused by the characteristics of light in photolithography, which is included in a semiconductor process for manufacturing integrated circuits. In the operation of manufacturing a mask, patterns on the mask may be defined to form patterns formed in a plurality of layers, and at least one mask (or photomask) may be manufactured to form the patterns in each of the plurality of layers. In the operation of fabricating an integrated circuit, the integrated circuit may be manufactured by patterning a plurality of layers using at least one manufactured mask, and may include a front-end-of-line (FEOL) process, a middle-of-line (MOL) process, and a back-end-of-line (BEOL) process.

Referring to FIGS. 1 and 2, a second floorplan A2 of a new second process may be designed from a first floorplan A1 of a first process of which the design has been completed. Information about the space of a circuit function block in which a specific digital circuit designed according to the first process is formed, may be defined as first floorplan information, and a first floorplan may be defined using the first floorplan information.

In the second floorplan A2 of the second process corresponding to the first floorplan A1 of the first process, the same digital circuit may be formed, whereas, as the process changes, the size of the circuit function block, locations of the input/output ports I/O2 arranged in the circuit function block, the size and locations of the macro cells arranged in the circuit function block, the size and location of a second blockage area BA2 in the circuit function block, etc., may change.

The first floorplan information of the first floorplan A1 may include shape and coordinate information about the space of the circuit function block. For example, the first floorplan information may include coordinates of each vertex P1 of the space where the circuit function block is formed, or lengths (e.g., L11 to L14) defining the space where the circuit function block is formed. The second floorplan information of the second floorplan A2 corresponding to the first floorplan A1 may include coordinates of each vertex P2 of the space where the circuit function block is formed, or lengths (e.g., L21 to L24) defining the space where the circuit function block is formed.

In addition, the first floorplan information of the first floorplan A1 may include information about input/output ports I/O1 connected to an input/output channel, and the information about the input/output ports I/O1 may include location coordinate information about the input/output ports I/O1 and may include information about input/output channels connected to the input/output ports I/O1. The second floorplan information of the second floorplan A2 corresponding to the first floorplan A1 may include location coordinate information about the input/output ports I/O2 and may include information about the input/output channels connected to the input/output ports I/O2.

In addition, the information floorplan information of the first floorplan A1 may include information about a blockage area BA1. The blockage area BA1 may refer to a space in which standard cells are not allowed to be arranged, or a space in which wiring for routing is not to be formed. Information about the blockage area BA1 may include information about coordinates in which the blockage area BA1 is arranged, and information about the size of the blockage area BA1. The second floorplan information about the second floorplan A2 corresponding to the first floorplan A1 may include information about a blockage area BA2.

In an embodiment, macro cells may be arranged in the blockage area BA1 of the first floorplan A1 and the blockage area BA2 of the second floorplan A2. Each of the first floorplan information about the first floorplan A1 and the second floorplan information about the second floorplan A2 may include macro cell information arranged in the circuit function block, and the macro cell information may include information about the type of the macro cells and the location in which the macro cells are arranged, and the size of the macro cells. For example, static random access memory (SRAM) cells may be arranged in the circuit function block, and the macro cell information may include information about the location in which SRAM cells are arranged, and the size of the SRAM cells.

In the floorplan operation S10, a floorplan of a new process may be generated using a floorplan of an initial process. Thus, compared to engineers having to redesign from the beginning, the functions and design features of digital circuits designed in a specific process may be maintained and automated for redesign in other processes, reducing the time required for floorplan design.

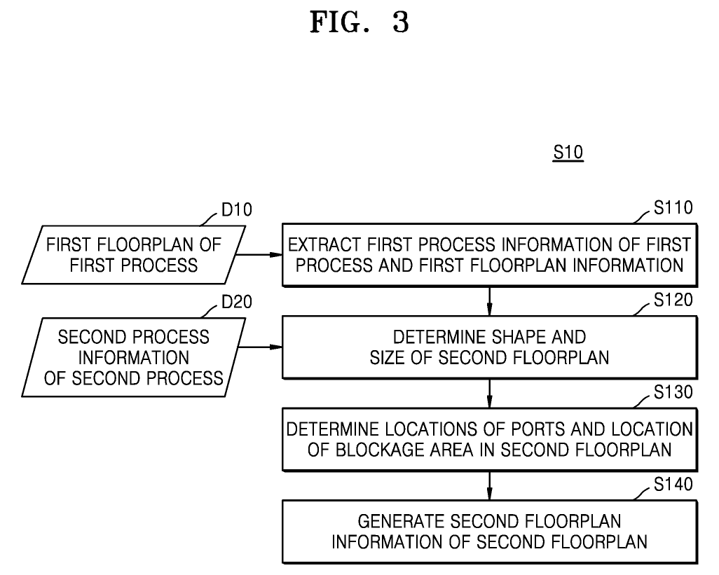

FIG. 3 is a flowchart illustrating a method of designing an integrated circuit according to an embodiment. More specifically, FIG. 3 is a flowchart illustrating a floorplan operation.

Referring to FIG. 3, the floorplan operation S10 may include operations S110 through S140. In the floorplan operation S10, a first floorplan D10 of the first process may be received, and second process information D20 of the second process may be received. In this case, the first process may refer to a process in which initial design is completed, and the second process may refer to a new process in which the integrated circuit described with reference to FIG. 1 is designed.

In operation S110, the first floorplan D10 of the first process may be received, and first process information of the first process and first floorplan information of the first process may be extracted from the floorplan D10 of the first process. In an embodiment, in operation S110, place and routing (P&R) information about the circuit function block in the first process may be further received, and the first process information and the first floorplan information may be extracted from the first floorplan D10 and the P&R information.

In operation S120, the second process information D20 of the second process may be received, and the shape and size of the second floorplan of the second process may be determined. For example, the second process information D20 received in operation S120 may include Verilog, Design Kit (DK), Process Design Kit (PDK), Synopsys Design Constraint (SDC), netlist, etc.

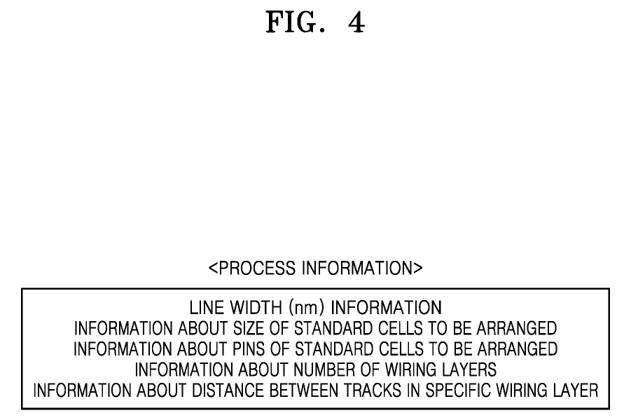

The first process information and the second process information will be described below in detail with reference to FIG. 4 and the like. The information extracted and received in operation S110 may be input and stored in a database (e.g., 136_1 of FIG. 12) of a computing system (e.g., 130 of FIG. 12).

In operation S120, the shape and the size of the second floorplan may be determined based on the first process information, the first floorplan information, and the second process information. As illustrated in FIG. 2, information about the coordinates of each vertex P2 of the second floorplan A2 or lengths (the width and the height, for example, L21 to L24) for defining a space in which the circuit function block is formed, may be determined.

In operation S130, locations of ports and the location of a blockage area to be arranged in the second floorplan may be determined. For example, information about the locations of ports (e.g., I/O1 in FIG. 2) arranged in the first floorplan and the location of a blockage area (e.g., BA1 in FIG. 2) arranged in the first floorplan may be obtained from the first floorplan information, and based on this, locations of ports (e.g., I/O2 in FIG. 2) arranged in the second floorplan and the location of a blockage area (e.g., BA2 in FIG. 2) arranged in the second floorplan may be determined.

After operation S130, the size of the second floorplan may be adjusted in consideration of the routing capability of the second floorplan for the routing to be arranged in the second floorplan. When the size of the second floorplan (e.g., the width and height defining the second floorplan) is adjusted, operation S130 may be re-performed.

In operation S140, second floorplan information including information about the shape, size, locations of ports, and location of the blockage area of the second floorplan may be generated. The second floorplan information may be output as a floorplan script.

FIGS. 4 through 6 are views for illustrating a method of designing an integrated circuit according to an embodiment. More specifically, FIGS. 4 through 6 are views for illustrating process information used in a floorplan operation.

Referring to FIG. 4, the first process information extracted from the floorplan (e.g., D10 of FIG. 3) of the first process and the second process information of the second process may include line width information representing dimensions in nanometers (nm). The line width information may refer to information about the line width of a circuit or information about the length of a channel of a transistor. The line width information may be a name that refers to the process, and a smaller number may indicate a more advanced line process.

The first process information and the second process information may include information about the size (e.g., a cell height) of standard cells arranged in the circuit function block, and may include information about pins of the standard cells arranged in the circuit function block. For example, information about the pins of the standard cells arranged in the circuit function block may include information about coordinates of input pins, coordinates of output pins, a wiring layer on which the input pins are formed, and a wiring layer on which the output pins are formed.

In addition, the first process information and the second process information may include at least one of the number of wiring layers formed in the circuit function block and a distance between tracks in a specific wiring layer.

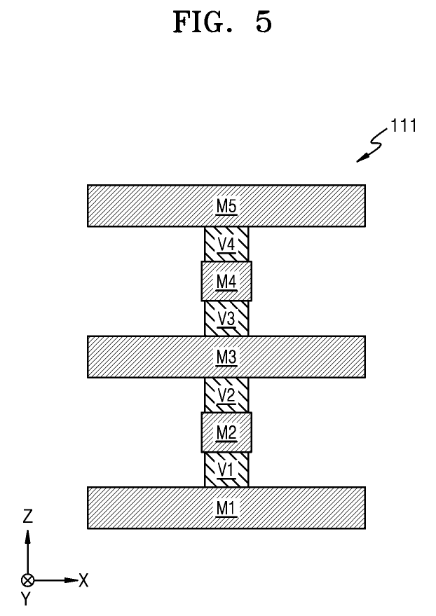

Referring to FIG. 5, a wiring structure formed in the circuit function block may include a plurality of wiring layers stacked in a vertical direction (e.g., in the Z-axis direction), for example, first to fifth wiring layers M1 to M5 and a plurality of first through fourth vias V1 to V4. The number of wiring layers shown in FIG. 5 is an example, and the number of wiring layers formed depending on the circuit function block may vary. Wiring layers in which power lines are arranged, may be determined using information about the number of wiring layers formed in the circuit function block included in the first process information and the second process information.

The first through fourth vias V1 to V4 may electrically connect the first through fifth wiring layers M1 to M5 located on different layers. For example, the first via V1 may be arranged between the first wiring layer M1 and the second wiring layer M2, thereby electrically connecting the first wiring layer M1 to the second wiring layer M2. Similarly, the second via V2 may be arranged between the second wiring layer M2 and the third wiring layer M3, thereby electrically connecting the second wiring layer M2 to the third wiring layer M3. The third via V3 may be arranged between the third wiring layer M3 and the fourth wiring layer M4, thereby electrically connecting the third wiring layer M3 to the fourth wiring layer M4. The fourth via V4 may be arranged between the fourth wiring layer M4 and the fifth wiring layer M5, thereby electrically connecting the fourth wiring layer M4 to the fifth wiring layer M5.

In an embodiment, a direction in which patterns extend may be specified in each of the plurality of wiring layers. For example, the first wiring layer M1 may be formed with patterns extending in a first horizontal direction (e.g., X-axis direction), and the second wiring layer M2 may be formed with patterns extending in a second horizontal direction (e.g., Y-axis direction). For example, the first, third, and fifth wiring layers M1, M3, and M5, which are odd layers, may have patterns formed that extend in the first horizontal direction, and the second and fourth wiring layers M2 and M4, which are even layers, may have patterns formed that extend in the second horizontal direction.

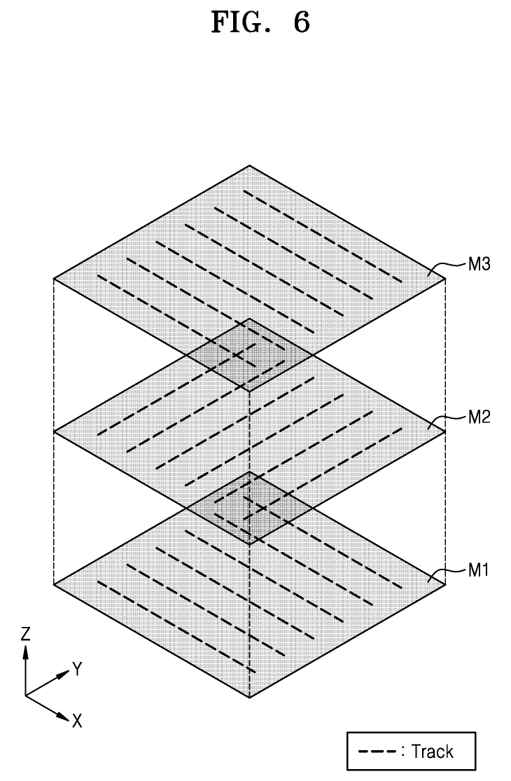

Referring to FIG. 6, each of the plurality of wiring layers may be defined as a track in which patterns are formed. For example, tracks on which patterns extend in the first horizontal direction X, may be defined in the first wiring layer M1, tracks on which patterns extend in the second horizontal direction Y, may be defined in the second wiring layer M2, and tracks on which patterns extend in the first horizontal direction X, may be defined in the third wiring layer M3. On the defined track, wires for transmitting signals between circuits constituting the circuit function block may be selectively arranged, or a first power line providing a power supply voltage VDD and a second power line providing a ground voltage VSS may be selectively arranged. Alternatively, a third power line may be further arranged on the track to provide a power supply voltage of a different voltage level than the power supply voltage VDD. In FIG. 6, the first to third wiring layers M1 to M3 are described as examples, but tracks may be defined similarly in other wiring layers. The shape and size of the floorplan may be determined using information about the distance between tracks in the wiring layer included in the first process information and the second process information.

In an embodiment, a distance between tracks defined in a specific layer may be defined to be constant. However, the disclosure is not limited thereto, and the distance between tracks may be designed to vary depending on the area even in the specific layer.

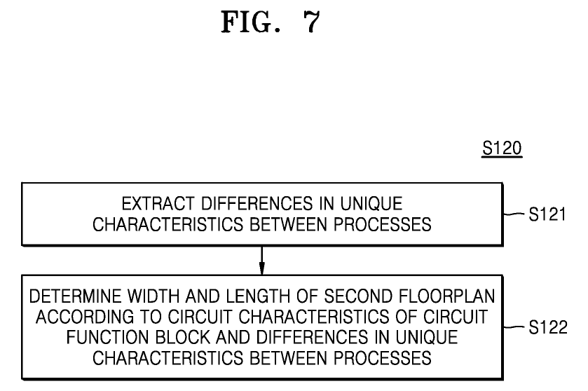

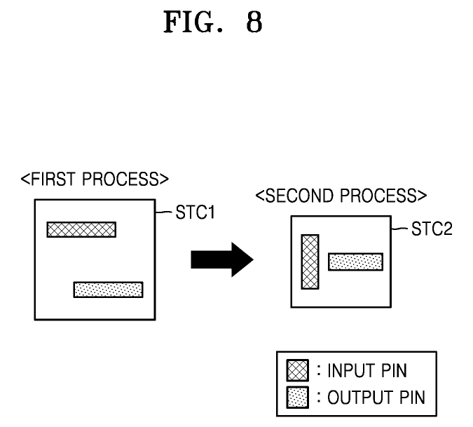

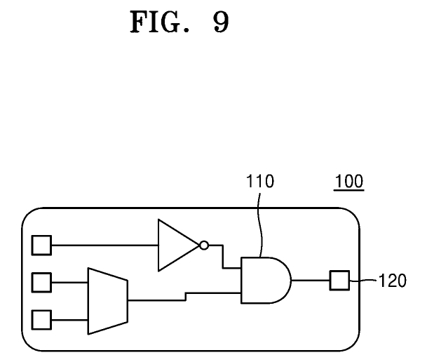

FIG. 7 is a flowchart for explaining a method of designing an integrated circuit according to an embodiment of the disclosure, and is a flowchart for explaining an example of operation S120 of FIG. 3. FIGS. 8 and 9 are views for explaining a method of designing an integrated circuit according to an embodiment. Operation S120 of FIG. 7 may include operations S121 and S122.

Referring to FIGS. 7 and 8, in operation S121, differences in unique characteristics between the first process and the second process may be extracted. The unique characteristics of the first process may include at least one of size information of the standard cells arranged in the first floorplan, pin coordinate information of the standard cells, and information about wiring layers in which the pins of the standard cells are formed. The unique characteristics of the second process may include at least one of size information of the standard cells arranged in the second floorplan, pin coordinate information of the standard cells, and information about a wiring layer on which the pins of the standard cells are formed.

The differences in the unique characteristics between the first and second processes may include differences (or changes) between the size of a first standard cell STC1 in which the same element is formed and which is used in the first process, and the size of a second standard cell STC2 used in the second process. For example, when the line width of the second process is reduced compared to the line width of the first process, the size of the second standard cell STC2 in which a specific element is formed, may be less than the size of the first standard cell STC1 in which the same element is formed.

Additionally, the differences in the unique characteristics between the first process and the second process may include differences in the coordinates of the input pins/output pins between the first standard cell STC1 in which the same element is used and which is used in the first process, and the second standard cell STC2 used in the second process, and may include differences in the vertical locations of the input pins/output pins between the first standard cell STC1 and the second standard cell STC2. For example, the differences in the unique characteristics between the first process and the second process may include changes in the coordinates on the horizontal plane on which the input pins/output pins of each of the first standard cell STC1 and the second standard cell STC2 are formed, and changes in the wiring layer on which the input pins/output pins are formed.

Referring to FIGS. 7 through 9, in operation S122, the width and the height of the second floorplan may be determined according to circuit characteristics of the circuit function block 100 and the differences in the unique characteristics between processes. The circuit characteristics of the circuit function block 100 may refer to information about circuit components 110 included in the circuit function block 100 and input/output ports 120 included in the circuit function block 100, and may refer to a netlist. That is, the circuit characteristics of the circuit function block 100 may include information about what circuit components (e.g., the type of standard cells to be arranged and the type of macro cells to be arranged) are arranged in the circuit function block 100 and what ports are arranged, and may include information about the connection relationship between the circuit components. Thus, components to be arranged in the second floorplan may be determined based on the circuit characteristics, and the size of the components to be arranged in the second floorplan and the change in the characteristics of the output pins/input pins may be determined based on the unique characteristic differences between the first process and the second process, thereby determining the length and the width for defining the size of the second floorplan.

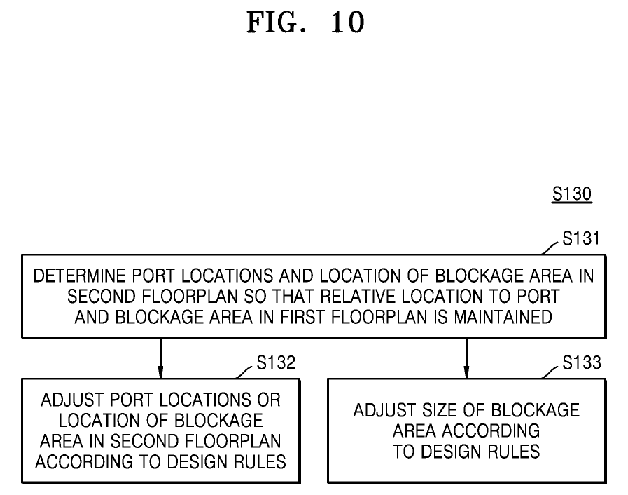

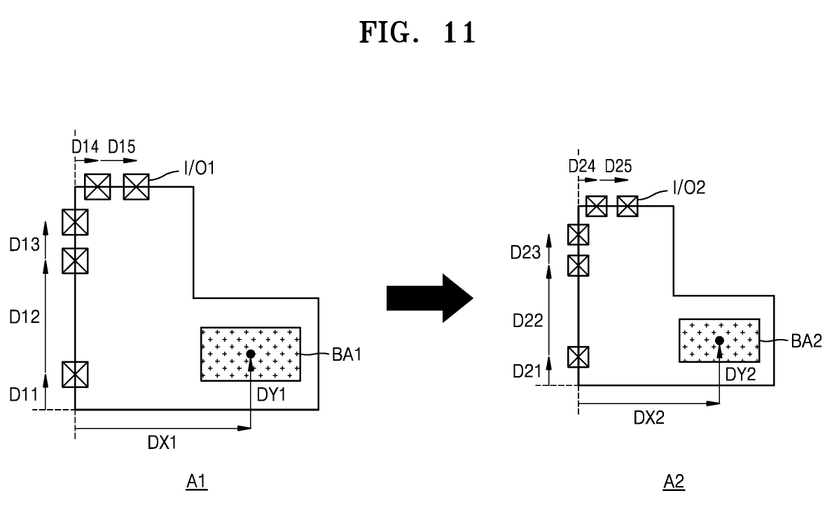

FIG. 10 is a flowchart for explaining a method of designing an integrated circuit according to an embodiment, and is a flowchart for explaining an example of operation S130 of FIG. 3. FIG. 11 illustrates views for explaining a method of designing an integrated circuit according to an embodiment. Operation S130 of FIG. 10 may include operations S131, S132 and S133.

Referring to FIGS. 10 and 11, in operation S131, port locations of the second floorplan A2 and the location of the blockage area BA2 may be determined so that relative locations of the ports and the blockage area BA1 in the first floorplan A1 may be maintained. Operation S131 may be performed based on the first floorplan information.

In operation S131, the locations of the plurality of input/output ports I/O2 in the second floorplan A2 may be determined so that the relative order in which the plurality of input/output ports I/O1 are arranged in the first floorplan A1, may be maintained. That is, the locations of the input/output ports I/O2 of the second floorplan A2 may be determined so that the order of the input/output channels connected to the input/output ports I/O1 of the first floorplan A1 may remain the same.

In an embodiment, distances D21 to D25 of the plurality of input/output ports I/O2 in the second floorplan A2 may be determined so that the relationship between distances D11 to D15 of the plurality of input/output ports I/O1 in the first floorplan A1 may be maintained. For example, the distances D21 to D25 between the plurality of input/output ports I/O2 in the second floorplan A2 may be determined so that the ratio of the distances D11 to D15 between the plurality of input/output ports I/O1 in the first floorplan A1 may be maintained.

Additionally, in operation S131, center coordinates DX2 and DY2 of the blockage area BA2 in the second floorplan A2 may be determined to correspond to center coordinates DX1 and DY1 of the blockage area BA1 in the first floorplan A1. Macro cells may be arranged in the blockage area BA1 or BA2, and the center coordinates of the area where the macro cells are arranged in the second floorplan, may also be determined to correspond to the center coordinates of the area where the macro cells are arranged in the first floorplan.

In operation S132, the port locations of the second floorplan A2 and the location of the blockage area BA2 may be adjusted according to the design rules of the second process, and in operation S133, the size of the blockage area BA2 may be adjusted according to the design rules of the second process. Operations S132 and S133 may be performed optionally. That is, only one of operations S132 and S133 may be performed, or both operations S132 and S133 may be performed.

For example, in the design rules of the second process, the rules for distances (e.g., minimum distances) between the plurality of input/output ports I/O2 may be specified, and specifically, the minimum value of the distances between the plurality of input/output ports I/O2 may be specified. In the case where the distances D21 to D25 of the plurality of input/output ports I/O2 of the second floorplan A2 determined in operation S131 have a value that violates the design rule (e.g., one or more of the distances D21 to D25 has a value smaller than the minimum value), the distances may be adjusted to satisfy the design rule.

For example, the design rules of the second process may include rules regarding the minimum space in which macro cells are arranged in the blockage area BA2, or the design rules of the second process may specify a space distance between a plurality of macro cells arranged in the second floorplan A2. Additionally, for example, the distances between the plurality of input/output ports I/O2 and the blockage area BA2 may be specified, and distances between a plurality of blockage areas BA2 may be specified when the plurality of blockage areas BA2 are arranged in the second floorplan A2. The design rules for the second process may also specify the distance at which the blockage area BA2 is separated from the boundary of the second floorplan A2. When the design rule is violated due to the location of the blockage area BA2 determined in operation S131, the center coordinates DX2 and DY2 of the blockage area BA2 may be adjusted (S132), or the size (the width and the height) of the blockage area BA2 may be adjusted (S132).

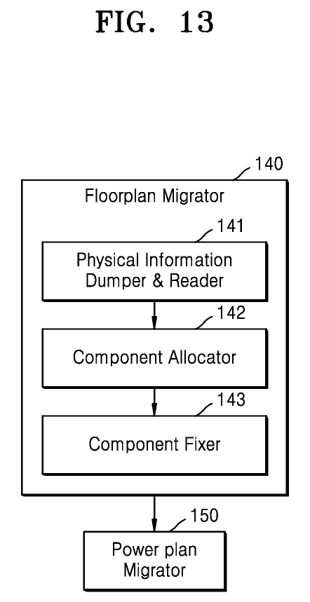

FIG. 12 is a block diagram illustrating a computing system 130 including memory for storing a program (i.e., software instructions) for designing an integrated circuit according to an embodiment. FIG. 13 is a block diagram for illustrating an example of a program 134_1 stored in the memory of FIG. 12.

Referring to FIG. 12, a method of designing an integrated circuit according to embodiments of the disclosure, for example, at least some of the operations of the flowchart described above, may be performed in the computing system (or computer) 130.

The computing system 130 may be a stationary computing system such as a desktop computer, workstation, server, etc., or may be a portable computing system such as a laptop computer. As illustrated in FIG. 12, the computing system 130 may include a processor 131, input/output devices 132, a network interface 133, random access memory (RAM) 134, read only memory (ROM) 135, and a storage device 136. The processor 131, the input/output devices 132, the network interface 133, the RAM 134, the ROM 135, and the storage device 136 may be connected to a bus 137 and may communicate with each other through the bus 137.

The processor 131 may be referred to as a processing unit and may include at least one core capable of executing any command set (e.g., Intel Architecture-32 (IA-32), 64-bit extended IA-32, x86-64, PowerPC, Sparc, MIPS, ARM, IA-64, etc.), such as a microprocessor, an application processor (AP), a digital signal processor (DSP), or a graphics processing unit (GPU). For example, the processor 131 may access memory, i.e., the RAM 134 or the ROM 135, through the bus 137 and execute commands stored in the RAM 134 or the ROM 135.

The RAM 134 may store a program 134_1 or at least a part thereof for the method of designing an integrated circuit according to an embodiment of the disclosure, and the program 134_1 may cause the processor 131 to perform the method of designing an integrated circuit, for example, at least a part of the operations of FIG. 1 or the operations of FIGS. 3, 7 and 10.

That is, the program 134_1 may include a plurality of commands executable by the processor 131, and the plurality of commands included in the program 134_1 may cause the processor 131 to perform at least some of the operations included in the flowcharts described above, for example.

Referring to FIGS. 12 and 13, the program 134_1 may include software instructions configured to implement a floorplan migrator 140 and a power plan migrator 150. For example, the floorplan migrator 140 may be executed by the processor 131 executing the software instructions to perform floorplan operation S10 described with reference to FIG. 1, and second floorplan information of the second floorplan may be generated. In addition, the software instructions may be executed by the processor 131 to control the power plan migrator 150 to perform power plan operation S20 described with reference to FIG. 1.

The floorplan migrator 140 may include a physical information dumper & reader 141, a component allocator 142, and a component fixer 143. Operation S110 of FIG. 3 may be performed by implementing the physical information dumper & reader 141 by the processor 131 executing the software instructions, and the first process information and the first floorplan information extracted according to the performance result may be input and stored in the database 136_1. By controlling the component allocator 142 implemented by the processor 131, the components to be arranged in the second floorplan may be determined, and operation S120 of FIG. 3 may be performed. In addition, operation S130 of FIG. 3, in which the locations and sizes of the components that constitute the circuit function block are determined to satisfy the design rules, may be performed by executing the software instructions by the processor 131 to implement the component fixer 143. Additionally, as the floorplan migrator 140 is controlled by the processor 131, the width and the height of the second floorplan may be adjusted based on the routing capability of the second floorplan.

By executing the software instructions to implement the power plan migrator 150, regular wiring patterns of power lines may be recognized in the power plan of the first process, new wiring patterns for power lines may be formed in the floorplan of the second process based on the recognized regular patterns, and second power plan information with the new wiring patterns inserted may be generated.

Referring to FIG. 12, the storage device 136 may be a non-volatile storage device which does not lose stored data even if the power supplied to the computing system 130 is cut off. For example, the storage device 136 may include a non-volatile memory device, or a storage medium such as a magnetic tape, an optical disc, or a magnetic disc. Additionally, the storage device 136 may be removable from the computing system 130. The storage device 136 may store the program 134_1 according to an embodiment of the disclosure, and the program 134_1 or at least a part thereof may be loaded from the storage device 136 into the RAM 134 before the program 134_1 is executed by the processor 131. Alternatively, the storage device 136 may store a file written in a programming language, and the program 134_1 or at least a part thereof generated by a compiler or the like from the file may be loaded into the RAM 134. Additionally, as illustrated in FIG. 12, the storage device 136 may store the database 136_1, and the database 136_1 may include information necessary for designing an integrated circuit, such as information about designed blocks, cell libraries, and/or design rules.

The storage device 136 may store data to be processed by the processor 131 or data processed by the processor 131. That is, the processor 131 may generate data by processing data stored in the storage device 136 according to the program 134_1, and may also store the generated data in the storage device 136. For example, the storage device 136 may store RTL data, netlist data, and/or layout data.

The input/output devices 132 may include input devices such as a keyboard, pointing device, etc., and may include output devices such as a display device, printer, etc. For example, a user may trigger the execution of the program 134_1 by the processor 131, input data, and check the layout data of FIG. 1 through the input/output devices 132. Additionally, the newly designed floorplan of the second process through the floorplan of the first process may be checked, and the newly designed power plan of the second process through the power plan of the first process may be checked.

The network interface 133 may provide access to a network outside the computing system 130. For example, the network may include a plurality of computing systems and communication links, and the communication links may include wired links, optical links, wireless links, or links having other arbitrary formats.

While aspects of embodiments have been particularly shown and described, it will be understood that various changes in form and details may be made therein without departing from the spirit and scope of the following claims.

What is claimed is:

1. A method of designing an integrated circuit performed by a computing system, the method comprising:
extracting first process information and first floorplan information from a first floorplan of a first process;
receiving second process information of a second process;
determining a shape and a size of a second floorplan based on the first process information, the first floorplan information and the second process information;
determining locations of ports and a location of a blockage area in the second floorplan; and
generating second floorplan information of the second floorplan based on the shape and the size of the second floorplan, and the locations of the ports and the location of the blockage area in the second floorplan.

2. The method of claim 1, wherein the second process information comprises any one or any combination of line width information of the second process, information about a size of standard cells arranged in the second floorplan, information about pins of the standard cells, information about a number of wiring layers, and information about a distance between tracks in a specific wiring layer.

3. The method of claim 1, wherein the second floorplan information comprises any one or any combination of a shape and coordinate information of the second floorplan, information about input/output ports connected to input/output channels, information about macro cells arranged in the second floorplan, and information about the blockage area where standard cells and wires are not arranged.

4. The method of claim 1, wherein the determining of the shape and the size of the second floorplan comprises:
extracting differences in unique characteristics between the first process and the second process; and
determining a width and a length of the second floorplan according to circuit characteristics of a circuit function block formed in the second floorplan and the differences in unique characteristics between the first and second processes.

5. The method of claim 4, wherein the unique characteristics of the second process comprise any one or any combination of size information of the standard cells used in the second process, coordinate information of pins of the standard cells, and information about wiring layers in which the pins of the standard cells are formed.

6. The method of claim 4, wherein the circuit characteristics comprise information about a connection relationship between circuit components that constitute the circuit function block.

7. The method of claim 1, wherein the determining the locations of the ports and the location of the blockage area arranged in the second floorplan comprises:
based on the first floorplan information, determining the locations of the ports and the location of the blockage area in the second floorplan such that relative locations of ports and a blockage area in the first floorplan are maintained; and
adjusting the locations of the ports and the location of the blockage area according to design rules of the second process.

8. The method of claim 7, wherein the design rules comprise rules regarding a minimum distance between a plurality of ports arranged in the second floorplan.

9. The method of claim 1, further comprising:
generating second power plan information based on the second floorplan information and a power plan of the first process, and
arranging standard cells, routing the standard cells, and generating layout data based on the second power plan information.

10. A method of designing an integrated circuit performed by a computing system, the method comprising:
based on first process information of a first process, first floorplan information of the first process, and second process information of a second process, determining a shape and a size of a second floorplan of the second process;
based on the first floorplan information, determining locations of ports and a location of a blockage area to be arranged in the second floorplan; and
generating second floorplan information of the second floorplan based on the shape and the size of the second floorplan, the locations of the ports and the location of the blockage area.

11. The method of claim 10, wherein the second process information comprises any one or any combination of line width information of the second process, information about a size of standard cells arranged in the second floorplan, information about pins of the standard cells, information about a number of wiring layers, and information about a distance between tracks in a specific wiring layer.

12. The method of claim 10, wherein the second floorplan information comprises any one or any combination of shape and coordinate information of the second floorplan, information about input/output ports connected to input/output channels, information about macro cells arranged in the second floorplan, and information about the blockage area where standard cells and wires are not arranged.

13. The method of claim 10, wherein the determining of the shape and the size of the second floorplan comprises:
extracting differences in unique characteristics between the first process and the second process; and
determining a width and a length of the second floorplan according to circuit characteristics of a circuit function block formed in the second floorplan and the differences in unique characteristics between the first and second processes.

14. The method of claim 13, wherein the unique characteristics of the second process comprise any one or any combination of size information of standard cells used in the second process, pin coordinate information of the standard cells, and information about wiring layers in which pins of the standard cells are formed.

15. The method of claim 10, wherein the determining of the locations of the ports and the location of the blockage area arranged in the second floorplan comprises:
based on the first floorplan information, determining the locations of the ports and the location of the blockage area in the second floorplan so that relative locations of ports and a blockage area in the first floorplan are maintained; and
adjusting the locations of the ports and the location of the blockage area according to design rules of the second process.

16. The method of claim 10, wherein the determining of the locations of the ports and the location of the blockage area arranged in the second floorplan comprises
based on the first floorplan information, determining the locations of the ports and the location of the blockage area in the second floorplan so that relative locations of ports and a blockage area in the first floorplan are maintained; and
adjusting the size of the blockage area according to design rules of the second process.

17. The method of claim 15, wherein the design rules comprise rules regarding a minimum space in which macro cells are arranged in the blockage area.

18. The method of claim 10, further comprising:
receiving a floorplan of the first process;
extracting the first process information and the first floorplan information from the floorplan of the first process; and
inputting the first process information and the first floorplan information to a database.

19. A computing system comprising:
one or more memories storing instructions; and
one or more processors configured to execute the instructions to:
extract first process information and first floorplan information from a floorplan of a first process;
determine a shape and a size of a second floorplan of a second process based on the first process information, the first floorplan information and second process information of the second process;
determine locations of ports and a location of a blockage area arranged in the second floorplan; and
generate second floorplan information of the second floorplan based on the shape and the size of the second floorplan, and the locations of the ports and the location of the blockage area in the second floorplan.

20. The computing system of claim 19, wherein the one or more processors are further configured to execute the instructions to input the first process information and the first floorplan information to a database.
